(19) United States
(12) Patent Application Publication
(10) Pub. No.: US 2025/0081753 A1
(43) Pub. Date: Mar. 6, 2025

(54) DISPLAY PANEL, MANUFACTURING METHOD THEREOF AND DISPLAY DEVICE

(71) Applicant: Visionox Technology Inc., Kunshan (CN)

(72) Inventor: Chao Chi PENG, Kunshan (CN)

(73) Assignee: Visionox Technology Inc., Kunshan (CN)

(21) Appl. No.: 18/950,205

(22) Filed: Nov. 18, 2024

(30) Foreign Application Priority Data
Dec. 28, 2023 (CN) 202311843533.1

(51) Int. Cl. H10K 59/122; H10K 59/12; H10K 59/80

(52) U.S. Cl. CPC H10K 59/122; H10K 59/1201; H10K 59/873

(57) ABSTRACT

A display panel, a manufacturing method thereof, and a display device are provided. The display panel includes a display area and an isolation area located on at least one side of the display area. The display panel includes a base substrate, and at least one first isolation structure located in the isolation area. The at least one first isolation structure includes at least two isolation bodies sequentially stacked along a direction away from the base substrate, and at least one sidewall of each of the at least two isolation bodies includes a recess region. At least one isolation body includes an electrically insulating portion.

### CROSS-REFERENCE TO RELATED APPLICATION

This application claims priority to Chinese Patent Application No. 202311843533.1, entitled “DISPLAY PANEL, MANUFACTURING METHOD THEREOF AND DISPLAY DEVICE” filed on Dec. 28, 2023, the content of which is hereby incorporated herein in its entirety by reference.

### TECHNICAL FIELD

The present disclosure relates to the technical field of display equipment, in particular to a display panel, a manufacturing method thereof, and a display device.

### BACKGROUND

With the development of display technology, organic light-emitting diode (OLED) display panels have been widely used due to their advantages such as lightweight and thinness, high brightness, low power consumption, fast response, and high resolution.

In the manufacturing process of the display panels, in order to prevent moisture from intruding and in turn affecting the normal operation of the OLED light-emitting materials, there is a need to set an isolation structure to block the external moisture. However, in related art, the isolation structures of the display panels are difficult to meet use requirements.

### SUMMARY

In view of this, there is a need to provide a display panel, a manufacturing method thereof, and a display device.

According to an aspect of the present disclosure, an embodiment of the present disclosure provides a display panel. The display panel includes a display area and an isolation area located on at least one side of the display area. The display panel includes a base substrate, and at least one first isolation structure located in the isolation area. The at least one first isolation structure includes at least two isolation bodies sequentially stacked along a direction away from the base substrate, and at least one sidewall of each of the at least two isolation bodies includes a recess region. At least one isolation body includes an electrically insulating portion.

In the above display panel, at least one first isolation structure is disposed in the isolation area, the first isolation structure includes at least two isolation bodies sequentially stacked along the direction away from the base substrate, and at least one sidewall of each isolation body includes a recess region, whereby the height of the first isolation structure in the direction perpendicular to the base substrate is relatively great, which can relatively completely isolate the light-emitting layer and the electrode layer of the display panel from the external environment. Moreover, as at least one isolation body includes an electrically insulating portion, the potential signals in the electrode layer of the display panel can be isolated from the external environment, avoiding structural damages caused by electrochemical corrosion, thereby improving the operation reliability of the first isolation structure.

In an embodiment, the at least one first isolation structure includes a first isolation body and a second isolation body sequentially stacked in the direction away from the base substrate, the first isolation body at least includes a first recess region located on a sidewall of the first isolation body adjacent to the display area, the second isolation body at least includes a second recess region located on a sidewall of the second isolation body adjacent to the display area, and the first isolation body includes the electrically insulating portion. Optionally, the first isolation body includes a first main body portion and a first barrier portion located on a side of the first main body portion away from the base substrate, the first recess region is located on a sidewall of the first main body portion, and the first barrier portion protrudes from the first main body portion along a direction from the isolation area to the display area. Optionally, an orthographic projection of the first barrier portion on the base substrate completely covers an orthographic projection of the first main body portion on the base substrate. Optionally, the second isolation body includes a second main body portion and a second barrier portion located on a side of the second main body portion away from the base substrate, the second recess region is located on a sidewall of the second main body portion, and the second barrier portion protrudes from the second main body portion along the direction from the isolation region to the display region. Optionally, an orthographic projection of the second barrier portion on the base substrate completely covers an orthographic projection of the second main body portion on the base substrate. Optionally, the orthographic projection of the first barrier portion on the base substrate completely covers the orthographic projection of the second main body portion on the base substrate. Optionally, the orthographic projection of the first barrier portion on the base substrate coincides with the orthographic projection of the second barrier portion on the base substrate. Optionally, the recess region is disposed around the sidewall of the isolation body, the first recess region is disposed around the sidewall of the first main body portion, and the second recess region is disposed around the sidewall of the second main body portion. With this arrangement, the first isolation body and the second isolation can jointly achieve the effect of isolating the light-emitting layer, the electrode layer, and the potential signals in the electrode layer of the display panel from the external environment, and the structure of the first isolation structure is relatively simple, which is convenient for processing and fabrication.

In an embodiment, the first isolation body further includes a first base portion located on a side of the first main body portion adjacent to the base substrate. Optionally, an orthographic projection of the first base portion on the base substrate completely covers the orthographic projection of the first main body portion on the base substrate. Optionally, at least a portion of the base substrate functions as the first base portion. Optionally, the second isolation body further includes a second base portion located on a side of the second main body portion adjacent to the base substrate. Optionally, an orthographic projection of the second base portion on the base substrate completely covers the orthographic projection of the second main body portion on the base substrate. Optionally, the first barrier portion and the second base portion are integrated as one piece.

In an embodiment, the first main body portion includes an insulating material, and the first barrier portion includes a first metal material. Optionally, the first main body portion includes an organic insulating material. Optionally, the second main body portion includes a second metal material, and the second barrier portion includes a third metal material. Optionally, an activity of the second metal material is greater than an activity of the first metal material, and/or, an activity of the second metal material is greater than an activity of the third metal material. Optionally, a material of the first barrier portion includes titanium, a material of the second main body portion includes aluminum, and a material of the second barrier portion includes titanium. In this way, the first main body portion in the first isolation body acts as the electrically insulating portion for isolating the potential signals in the electrode layer of the display panel from the external environment, thereby achieving a relatively good isolation effect, without affecting the function of the second isolation body.

In an embodiment, along the direction from the isolation area to the display area, a length size of a protruding portion of the first barrier portion protruding from the first main body portion is d1, where 0.2 μm≤d1≤0.4 μm; and/or along the direction from the isolation area to the display area, a length size of a protruding portion of the second barrier portion protruding from the second main body portion is d2, where 0.2 μm≤d2≤0.4 μm. Optionally, along a direction perpendicular to the base substrate, a height size of the first main body portion is h1, where 1 μm≤h1≤1.5 μm. Optionally, along the direction perpendicular to the base substrate, a sum of the height sizes of the first isolation body and the second isolation body is h2, where 2.1 μm≤h2≤2.3 μm. By setting the length size of the protruding portion of the first barrier portion protruding from the first main body portion satisfying 0.2 μm≤d1≤0.4 μm, the undercut structure formed by the first main body portion and the first barrier portion is relatively stable, thereby exerting a good isolation effect, and facilitating the processing and manufacture of the first isolation body.

In an embodiment, the at least one first isolation structure comprises a plurality of first isolation structures, and the plurality of first isolation structures are spaced from each other along the direction from the display area to the isolation area. Optionally, a distance between two adjacent first isolation structures of the plurality of first isolation structures is L1, where 8 μm≤L1≤12 μm. Optionally, a distance between one of the plurality of first isolation structures and the display area is L2, where 8 μm≤L2≤12 μm. By providing a plurality of first isolation structures, the plurality of first isolation structures work together to ensure the effect of isolating the light-emitting layer, the electrode layer, and the potential signals in the electrode layer of the display panel from the external environment, thereby improving the operation reliability thereof.

In an embodiment, the display panel further includes at least one second isolation structure located in the isolation area, the at least one second isolation structure and the at least one first isolation structure are spaced from each other, the at least one second isolation structure includes at least one isolation body sequentially stacked along the direction away from the base substrate, and at least one sidewall of the isolation body includes a recess region. Optionally, the at least one second isolation structure includes a third isolation body stacked on the base substrate, and the third isolation body includes a third recess region located at least on a sidewall of third isolation body adjacent to the display area. Optionally, the third isolation body includes a third main body portion and a third barrier portion located on a side of the third main body portion away from the base substrate, the third recess region is located on a sidewall of the third main body portion, and the third barrier portion protrudes from the third main body portion along the direction from the isolation area to the display area. Optionally, the recess region is disposed around the sidewall of the isolation body, and the third recess region is disposed around the sidewall of the third main body portion. Optionally, an orthographic projection of the third barrier portion on the base substrate completely covers an orthographic projection of the third main body portion on the base substrate. Optionally, the third isolation body further includes a third base portion located on a side of the third main body portion adjacent to the base substrate.

Optionally, an orthographic projection of the third base portion on the base substrate completely covers the orthographic projection of the third main body portion on the base substrate. By providing the at least one second isolation structure, the at least one second isolation structure can work together with the at least one first isolation structure, thereby ensuring the effect of isolating the light-emitting layer, the electrode layer, and the potential signals in the electrode layer of the display panel from the external environment, thereby improving the operation reliability thereof. Furthermore, the overall structure of the at least one second isolation structure can be relatively simple, which is convenient for processing and manufacturing the at least one second isolation structure.

In an embodiment, the at least one second isolation structure is located on a side of the at least one first isolation structure away from the display area. Optionally, the at least one second isolation structure comprises a plurality of second isolation structures, and the plurality of second isolation structures are spaced from each other along the direction from the display area to the isolation area. Optionally, all of the plurality of second isolation structures are located on the side of the at least one first isolation structure away from the display area. Optionally, a distance between two adjacent second isolation structures of the plurality of second isolation structures is L3, where 8 μm≤L3≤12 μm. Optionally, a distance between one of the plurality of second isolation structures and the at least one first isolation structure is L4, wherein 8 μm≤L4≤12 μm. Optionally, an orthographic projection of the display area on the base substrate includes a first projection pattern, an orthographic projection of the isolation area on the base substrate includes a second projection pattern, and the first projection pattern surrounds at least a part of the second projection pattern. Optionally, the display panel further includes a penetration area, an orthographic projection of the penetration area on the base substrate includes a third projection pattern, and the second projection pattern surrounds at least a part of the third projection pattern. Optionally, the second projection pattern includes an annular shape, and the second projection pattern completely surrounds the third projection pattern. Optionally, the orthographic projection of the isolation area on the base substrate further includes a fourth projection pattern, the fourth projection pattern surrounds at least a part of the first projection pattern. Optionally, the fourth projection pattern includes an annular shape, and the fourth projection pattern completely surrounds the first projection pattern. Optionally, the display panel further includes at least one dam structure located in the isolation area, and the at least one first isolation structure comprises a plurality of first isolation structures; at least one of the plurality of first isolation structures is located on a side of the dam structure adjacent to the display area, and/or at least one of the plurality of first isolation structures is located on a side of the dam structure away from the display area. In this way, the first isolation structure is located relatively close to the display area, so that the first isolation structure can provide a relatively tight isolation effect at a position relatively close to the display area, thereby exerting a good protecting effect for the display area.

According to another aspect of the present disclosure, an embodiment of the present disclosure provides a method for manufacturing a display panel, including: sequentially stacking at least two isolation bodies on a base substrate at a position corresponding to an isolation area of a display panel, at least one isolation body including an electrically insulating portion; and forming a recess region on at least one sidewall of each isolation body. The display panel manufactured by the above-described method has a simple and convenient manufacturing process. At least one first isolation structure is formed in the isolation area of the display panel, and the first isolation structure includes at least two isolation bodies sequentially stacked along the direction away from the base substrate, whereby the height of the first isolation structure in the direction perpendicular to the base substrate is relatively great, which can relatively completely isolate the light-emitting layer and the electrode layer of the display panel from the external environment. Moreover, as at least one isolation body includes an electrically insulating portion, the potential signals in the electrode layer of the display panel can be isolated from the external environment, avoiding structural damages caused by electrochemical corrosion, thereby improving the operation reliability of the first isolation structure.

According to yet another aspect of the present disclosure, an embodiment of the present disclosure provides a display device, including the display panel as described above.

In the above-described display device, by adopting the above-described display panel, the light-emitting layer and the electrode layer of the display panel can be relatively completely isolated from the external environment, and the potential signals in the electrode layer of the display panel can be isolated from the external environment, avoiding structural damages caused by electrochemical corrosion, thereby improving the operation reliability of the first isolation structure.

### BRIEF DESCRIPTION OF THE DRAWINGS

FIG. 1 shows a schematic structural cross-sectional view of a display panel according to an embodiment of the present disclosure.

FIG. 2 shows a schematic structural cross-sectional view of a first isolation structure of a display panel according to an embodiment of the present disclosure.

FIG. 3 shows a schematic structural cross-sectional view of a first isolation structure of a display panel according to another embodiment of the present disclosure.

FIG. 4 shows a schematic structural cross-sectional view of a second isolation structure of a display panel according to an embodiment of the present disclosure.

FIG. 5 shows a schematic structural cross-sectional view of a second isolation structure of a display panel according to another embodiment of the present disclosure.

FIG. 6 shows a flowchart of a method for manufacturing a display panel according to an embodiment of the present disclosure.

FIG. 7 shows an overall schematic structural view of a display device according to

an embodiment of the present disclosure.

FIG. 8 shows a schematic structural view of a display panel in a display device according to another embodiment of the present disclosure.

The reference signs in the embodiments are as follows:

1: display device;

10: display panel;

100: base substrate;

200: first isolation structure, 210: first isolation body, 210A: first recess region, 211: first main body portion, 212: first barrier portion, 213: first base portion, 220: second isolation body, 220A: second recess region, 221: second main body portion, 222: second barrier portion, 223: second base portion;

300: second isolation structure, 310: third isolation body, 310A: third recess region, 311: third main body portion, 312: third barrier portion, 313: third base portion;

400: dam structure;

500: interlayer medium layer, 510: first planarization layer, 520: second planarization

layer, 530: pixel definition layer;

600: light-emitting function portion, 610: first electrode, 620: light-emitting function layer, 630: second electrode;

700: encapsulation layer, 710: first sub-encapsulation layer, 720: second sub-encapsulation layer, 730: third sub-encapsulation layer;

AA: display area, VA: isolation area, VA1: first isolation area, VA2: second isolation area, HA: penetration area.

### DETAILED DESCRIPTION

The embodiments of the present disclosure will be described in detail below in conjunction with the accompanying drawings, in order to make the above objects, features and advantages of the present disclosure more apparent and understandable. Numerous specific details are set forth in the following description in order to facilitate a thorough understanding of the present disclosure. However, the present disclosure can be implemented in many other ways than those describe herein, and similar modifications can be made by those skilled in the art without departing from the concept of the present disclosure, and thus the present disclosure is not limited to the embodiments disclosed below.

In the description of the present disclosure, it should be understood that, with regard to the terms “central”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, “axial”, “radial”, “circumferential”, etc., the orientation or position relationships indicated by these terms are based on the orientation or position relationships shown in the accompanying drawings, and are intended to facilitate the description of the present disclosure and simplify the description only, rather than indicating or implying that the apparatus or element referred to must have a particular orientation or be constructed and operated in a particular orientation, and therefore these terms are not to be interpreted as limiting the present disclosure.

In addition, with regard to the terms “first” and “second”, these terms are used for descriptive purposes only, and cannot be construed as indicating or implying a relative importance, or implicitly specifying the number of the indicated technical features. Thus, the feature defined with “first” or “second” may explicitly or implicitly be at least one in quantity. In the description of the present disclosure, when the term “a plurality of” is used herein, the term “a plurality of” means at least two, such as two or three, unless otherwise defined explicitly and specifically.

In the present disclosure, unless otherwise specified and defined explicitly, with regard to the terms “install”, “connect”, “join”, and “fix”, these terms should be understood in a broad sense. For example, they may refer to a fixed connection, a detachable connection, or an integral connection, may refer to a mechanical connection or electrical connection, and may refer to a direct connection, an indirect connection via an intermediate medium, an internal connection between two elements, or interaction between two elements, unless otherwise defined explicitly. Those of ordinary skill in the art can understand specific meanings of these terms in the present disclosure based on specific circumstances.

In the present disclosure, unless otherwise specified and defined explicitly, when a first feature is expressed as being “on” or “under” a second feature herein, it means that the first feature is in direct contact with the second feature, or the first feature is in indirect contact with the second feature via an intermediate medium. Furthermore, the first feature being “over”, “above” or “on top of” the second feature may be the case that the first feature is directly above or obliquely above the second feature, or only means that the level of the first feature is higher than that of the second feature. The first feature being “below”, “underneath” or “under” the second feature may be the case that the first feature is directly underneath or obliquely underneath the second feature, or only means that the level of the first feature is lower than that of the second feature.

It should be noted that when one element is referred to as “fixed to” or “arranged on” another element, it may be directly disposed on the other element or an intermediate element may exist. When one element is considered to be “connected to” another element, it may be directly connected to the other element or an intermediate element may co-exist. The terms “vertical”, “horizontal”, “upper”, “lower”, “left”, “right” and similar expressions used herein, if any, are for illustrative purposes only and do not represent the only implementation.

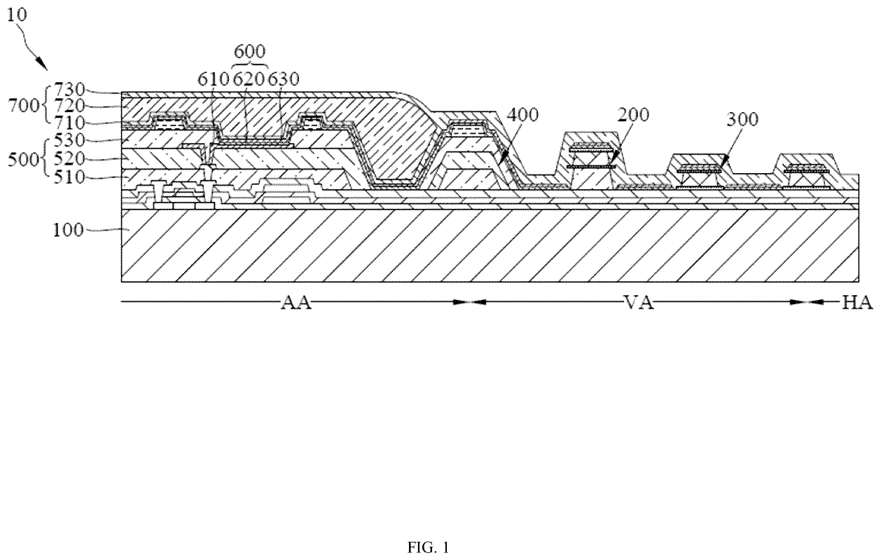

FIG. 1 shows a schematic structural cross-sectional view of a display panel according to an embodiment of the present disclosure. FIG. 2 shows a schematic structural cross-sectional view of a first isolation structure of a display panel according to an embodiment of the present disclosure.

Referring to FIGS. 1 to 2, an embodiment of the present disclosure provides a display panel 10. The display panel 10 includes a display area AA and an isolation area VA located on at least one side of the display area AA. The display panel 10 includes a base substrate 100 and at least one first isolation structure 200. The first isolation structure 200 is located in the isolation area VA. The first isolation structure 200 includes at least two isolation bodies stacked in sequence along a direction away from the base substrate 100. At least one sidewall of each isolation body includes a recess region. At least one isolation body includes an electrically insulating portion.

The display panel 10 displays an image by arranging a plurality of light-emitting function portions 600 in the display area AA. Specifically, the display area AA can be rectangular, and the isolation area VA is located on at least one side of the display area AA. Certainly, the shape and arrangement of the display area AA and the isolation area VA include, but are not limited to, the above-described example. For example, when the display panel 10 is applied in a wearable device worn by a user, the display area AA can have a circular shape like a watch. When the display panel 10 is applied in a vehicle for display, the display area AA and the isolation area VA can be, for example, a circular shape, a polygonal shape, or other shapes. The display area AA includes a plurality of light-emitting function portions 600 configured for emitting lights of different colors, and the light-emitting function portions 600 are minimum units for emitting lights.

The isolation area VA is an area of the display panel 10 for isolating the display area AA from the external environment. For example, in the display panel 10 including a hole or a notch, such as a “hole-punch screen” or a “notch screen”, the isolation area VA can be provided between a penetration area HA and the display area AA, wherein the hole or notch is located in the penetration area HA, so as to isolate the display area AA and the penetration area HA from each other. In some other embodiments, the isolation area VA can also be provided at the outer boundary of the display area AA, that is, at the display edge position of the display area AA, to isolate the display area AA from a non-display area.

The base substrate 100 is configured to support and carry other films or layers in the display panel 10. For example, the base substrate 100 can be made of glass, polyimide (PI), etc. A drive circuit layer can be disposed on the base substrate 100. The drive circuit layer can include a thin film transistor, etc.

The display panel 10 according to an embodiment of the present disclosure can be an organic light-emitting display panel. The light-emitting function portion 600 can include a first electrode 610, a second electrode 630, and a light-emitting function layer 620 located between the first electrode 610 and the second electrode 630. One of the first electrode 610 and the second electrode 630 is an anode, and the other is a cathode. The drive circuit layer applies a voltage between the anode and the cathode to excite the migration of carriers, which acts on the light-emitting function layer 620, thereby emitting light. The light-emitting function layer 620 can include a multi-layer structure. For example, each light-emitting function layer 620 includes a hole injection portion, a hole transport portion, a light-emitting portion, an electron transport portion, an electron injection portion, etc. (not shown), which are stacked one on another.

The display panel 10 can further include an interlayer medium layer 500. The interlayer medium layer 500 can include a plurality of films or layers with different functions. For example, the interlayer medium layer 500 includes a first planarization layer 510, a second planarization layer 520, and a pixel definition layer 530, which are stacked one on another. The pixel definition layer 530 defines a plurality of pixel openings spaced apart from each other. The light-emitting function portion 600 is at least partially located in a pixel opening. The pixel definition layer 530 can be disposed in the same layer as the first electrode 610 of the light-emitting function portion 600, and the first electrode 610 is at least partially exposed from the pixel opening for normal light emission of the light-emitting function portion 600.

The first isolation structure 200 is disposed on one side of the base substrate 100 and is located in the isolation area VA. The first isolation structure 200 is configured to block moisture transmission channels. Therefore, the first isolation structure 200 can be disposed around the penetration area HA. As such, the moisture entering the display panel 10 from the penetration area HA can be prevented from reaching the display area AA along the moisture transmission channels. The specific position of the first isolation structure 200 in the isolation area VA and the specific structure form of the first isolation structure 200 are not limited, as long as the first isolation structure 200 can partition the films or layers forming the moisture transmission channels.

The first isolation structure 200 includes at least two isolation bodies sequentially stacked along the direction away from the base substrate 100. That is, the first isolation structure 200 can include two, three, four, or other numbers of isolation bodies, and the isolation bodies are sequentially stacked on the base substrate 100, such that the height of the first isolation structure 200 along the direction perpendicular to the base substrate 100 is relatively great, so as to relatively completely isolate the films or layers such as the light-emitting layer and the electrode layers in the display panel 10 from the external environment. Therefore, the specific number of the isolation bodies can be flexibly set according to varied application scenarios. At least one sidewall of each isolation body includes a recess region. As including the recess region, the sidewall of the isolation body also includes a protrusion region protruding relative to the recess region. The recess region and the protrusion region can together form an undercut structure, so that in the manufacturing process of the display panel 10, the light emitting layer and the electrode layer can be disconnected at the position of the undercut structure, thereby blocking the films or layers forming the moisture transmission channels. In other embodiments, the recess region can be disposed around the sidewall of the isolation body, with each sidewall of the isolation body being provided with the recess region.

At least one isolation body in the first isolation structure 200 includes an electrically insulating portion. The electrically insulating portion in the isolation body is capable of isolating potential signals in the electrode layer of the display panel 10 from the external environment, avoiding structural damages due to electrochemical corrosion. Specifically, the electrochemical corrosion means that the electrode layer and water and oxygen in the air constitute two electrodes to form a corrosion primary battery. Because the electrode potential of the electrode layer is always lower than the electrode potential of water and oxygen, the electrode layer is an anode electrode to lose electrons, and thus to be oxidized and corroded.

In some embodiments, the isolation body can include different portions made of a variety of materials, including a conductive portion made of a conductive material and an electrically insulating portion made of an insulating material. In some other embodiments, the isolation body can be entirely made of the insulating material, so that the isolation body as a whole serves as the electrically insulating portion. In the first isolation structure 200, any one of the isolation bodies can include the electrically insulating portion, or some of the isolation bodes can include electrically insulating portions, or each of the isolation bodies can include the electrically insulating portion, which can be flexibly adjusted according to different application requirements in actual application processes.

In the display panel 10 according to the embodiments of the present disclosure, the first isolation structure 200 is provided in the isolation area VA, the first isolation structure 200 includes at least two isolation bodies sequentially stacked along the direction away from the base substrate 100, and at least one sidewall of each isolation body includes a recess region, whereby the height of the first isolation structure 200 along the direction perpendicular to the base substrate 100 is relatively great, so that the first isolation structure 200 can relatively completely isolate the light-emitting layer and the electrode layer of the display panel 10 from the external environment. Moreover, since at least one isolation body includes an electrically insulating portion, the potential signals in the electrode layer of the display panel 10 can be isolated from the external environment, thereby avoiding structural damages due to electrochemical corrosion, thereby improving the operation reliability of the first isolation structure 200.

The first isolation structure 200 includes at least two isolation bodies sequentially stacked along the direction away from the base substrate 100. In order to simplify the overall structure of the first isolation structure and thus facilitate the processing and fabrication thereof on the premise that the first isolation structure 200 can exert its isolation effect, in some embodiments, specifically, the first isolation structure 200 includes a first isolation body 210 and a second isolation body 220 which are sequentially stacked along the direction away from the base substrate 100. The first isolation body 210 at least includes a first recess region 210A located on the sidewall of the first isolation body 210 adjacent to the display area AA. The second isolation body 220 includes at least a second recess region 220A located on the sidewall of the second isolation body 220 adjacent to the display area AA. The first isolation body 210 includes the electrically insulating portion.

The first isolation structure 200 includes a first undercut structure and a second undercut structure. In some embodiments, the first recess region 210A of the first isolation body 210 can form the first undercut structure, and the second recess region 220A of the second isolation body 220 can form the second undercut structure, so that each of the first isolation body 210 and the second isolation body 220 in the first isolation structure 200 can exert the isolation effect. Specifically, each of the first isolation body 210 and the second isolation body 220 can isolate the light-emitting layer and the electrode layer of the display panel 10 from the external environment. Moreover, since the first isolation body 210 includes the electrically insulating portion, the first isolation body 210 can also isolate the potential signals in the electrode layer of the display panel 10 from the external environment. The first isolation body 210 and the second isolation body 220 may or may not have the same structure and the same size, which be decided according to the actual situation. In other embodiments, two sidewalls of the first isolation body 210 each include a recess region, two sidewalls of the second isolation body 220 each include a recess region, and the first isolation body 210 includes the electrically insulating portion.

Regarding the specific structures of the first isolation body 210 and the second isolation body 220, for example, the first isolation body 210 can include a first main body portion 211 and a first barrier portion 212 located on the side of the first main body portion 211 away from the base substrate 100. The first recess region 210A is located on the sidewall of the first main body portion 211 adjacent to the display area AA. The first barrier portion 212 protrudes from the first main body portion 211 along the direction from the isolation area VA to the display area AA. In the first isolation body 210, the first main body portion 211 can include the electrically insulating portion, or the first barrier portion 212 can include the electrically insulating portion, or the first main body portion 211 and the first barrier portion 212 can each include an electrically insulating portion, which is not limited herein.

Similarly, the second isolation body 220 can include a second main body portion 221 and a second barrier portion 222 located on the side of the second main body portion 221 away from the base substrate 100. The second recess region 220A is located on the sidewall of the second main body portion 221 adjacent to the display area AA. The second barrier portion 222 protrudes from the second main body portion 221 along the direction from the isolation area VA to the display area AA.

In some embodiments, the first recess region 210A can be disposed around the sidewall of the first main body portion 211, and each sidewall of the first main body portion 211 is provided with a first recess region 210A. The second recess region 220A can be disposed around the sidewall of the second main body portion 221, and each sidewall of the second main body portion 221 is provided with a second recess region 220A. It can be understood that the number of the sidewalls of each of the first isolation body 210 and the second isolation body 220 is two: the sidewall adjacent to the display area AA and the sidewall away from the display area AA.

With this arrangement, the first isolation body 210 and the second isolation body 220 can jointly exert the effect of isolating the light-emitting layer, the electrode layer, and the potential signals in the electrode layer of the display panel 10 from the external environment, and the structure of the first isolation structure 200 is relatively simple, which is convenient for processing and fabrication.

In some embodiments, optionally, an orthographic projection of the first barrier portion 212 on the base substrate 100 completely covers an orthographic projection of the first main body portion 211 on the base substrate 100; that is, along the direction perpendicular to the surface of the base substrate 100, the area of the projection pattern of the first barrier portion 212 on the surface of the base substrate 100 is larger than the area of the projection pattern of the first main body portion 211 on the surface of the base substrate 100, so that the projection pattern of the first barrier portion 212 on the surface of the base substrate 100 can completely cover the projection pattern of the first main body portion 211 on the surface of the base substrate 100, thereby forming the undercut structure in the first isolation body 210.

Since the second isolation body 220 is stacked on the first isolation body 210, in order to facilitate the arrangement and formation of the second isolation body 220, in some embodiments, optionally, the orthographic projection of the first barrier portion 212 on the base substrate 100 completely covers an orthographic projection of the second main body portion 221 on the base substrate 100; that is, along the direction perpendicular to the surface of the base substrate 100, the area of the projection pattern of the first barrier portion 212 on the surface of the base substrate 100 is larger than the area of the projection pattern of the second main body portion 221 on the surface of the base substrate 100, so that the projection pattern of the first barrier portion 212 on the surface of the base substrate 100 can completely cover the projection pattern of the second main body portion 221 on the surface of the base substrate 100.

Similarly to the above embodiment, an orthographic projection of the second barrier portion 222 on the base substrate 100 completely covers the orthographic projection of the second main body portion 221 on the base substrate 100; that is, along the direction perpendicular to the surface of the base substrate 100, the area of the projection pattern of the second barrier portion 222 on the surface of the base substrate 100 is larger than the area of the projection pattern of the second main body portion 221 on the surface of the base substrate 100, so that the projection pattern of the second barrier portion 222 on the surface of the base substrate 100 can completely cover the projection pattern of the second main body portion 221 on the surface of the base substrate 100, thereby forming the undercut structure in the second isolation body 220. Moreover, the orthographic projection of the first barrier portion 212 on the base substrate 100 coincides with the orthographic projection of the second barrier portion 222 on the base substrate 100; that is, along the direction perpendicular to the surface of the base substrate 100, the area of the projection pattern of the first barrier portion 212 on the surface of the base substrate 100 is equal to the area of the projection pattern of the second barrier portion 222 on the surface of the base substrate 100, so that the orthographic projection pattern of the first barrier portion 212 on the base substrate 100 can coincide with the orthographic projection pattern of the second barrier portion 222 on the base substrate 100.

In addition to the main body portion and the barrier portion, in some other embodiments, optionally, the first isolation body 210 further includes a first base portion 213 located on the side of the first main body portion 211 adjacent to the base substrate 100; that is, the first base portion 213, the first main body portion 211, and the first barrier portion 212 are sequentially stacked on the base substrate 100, constituting the first isolation body 210. Similarly, the second isolation body 220 further includes a second base portion 223 located on the side of the second main body portion 221 adjacent to the base substrate 100; that is, the second base portion 223, the second main body portion 221, and the second barrier portion 222 are stacked sequentially on the base substrate 100, constituting the second isolation body 220.

The first base portion 213 is configured to carry the first main body portion 211, and the second base portion 223 is configured to carry the second main body portion 221. In order to improve the structural stability of the first isolation body 210 and the second isolation body 220, in some embodiments, optionally, an orthographic projection of the first base portion 213 on the base substrate 100 completely covers the orthographic projection of the first main body portion 211 on the base substrate 100; that is, along the direction perpendicular to the surface of the base substrate 100, the area of the projection pattern of the first base portion 213 on the surface of the base substrate 100 is larger than the area of the projection pattern of the first main body portion 211 on the surface of the base substrate 100, so that the projection pattern of the first base portion 213 on the surface of the base substrate 100 can completely cover the projection pattern of the first main body portion 211 on the surface of the base substrate 100.

Similarly to the above embodiment, an orthographic projection of the second base portion 223 on the base substrate 100 completely covers the orthographic projection of the second main body portion 221 on the base substrate 100; that is, along the direction perpendicular to the surface of the base substrate 100, the area of the projection pattern of the second base portion 223 on the surface of the base substrate 100 is larger than the area of the projection pattern of the second main body portion 221 on the surface of the base substrate 100, so that the projection pattern of the second base portion 223 on the surface of the base substrate 100 can completely cover the projection pattern of the second main body portion 221 on the surface of the base substrate 100.

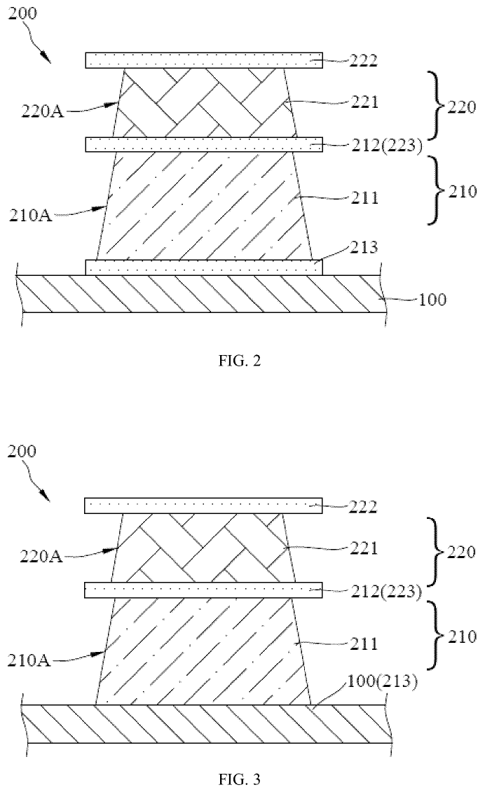

FIG. 3 shows a schematic structural cross-sectional view of the first isolation structure 200 of the display panel 10 according to another embodiment of the present disclosure.

In some embodiments, the first base portion 213 is disposed on the base substrate 100, and the first main body portion 211 is disposed on the first base portion 213. In order to simplify the overall structure of the first isolation structure 200, referring to FIG. 1 in conjunction with FIG. 3, in some embodiments, optionally, at least a part of the base substrate 100 can function as the first base portion 213; that is, the first base portion 213 and the base substrate 100 can be integrated as one piece without an additional first base portion 213, thereby simplifying the fabrication process. That is, as shown in FIG. 3, in some embodiments, the first isolation body 210 can include a portion of the base substrate 100, the first main body portion 211, and the first barrier portion 212 that are stacked in sequence.

In order to simplify the overall structure of the first isolation structure 200, in some embodiments, optionally, the first barrier portion 212 and the second base portion 223 are integrated as one piece; that is, the first barrier portion 212 of the first isolation body 210 can function as the second base portion 223 of the second isolation body 220. The first isolation body 210 and the second isolation body 220 share a portion of structure, which simplifies the overall structure of the first isolation structure 200 and facilitates its processing and fabrication without affecting its normal function and application. That is, as shown in FIG. 3, in some embodiments, the first isolation structure 200 can include a portion of the base substrate 100, the first main body portion 211, the first barrier portion 212, the second main body portion 221, and the second barrier portion 222 that are stacked in sequence.

In the first isolation body 210, the first main body portion 211 can include the electrically insulating portion, or the first barrier portion 212 can include the electrically insulating portion, or the first main body portion 211 and the first barrier portion 212 can each include an electrically insulating portion. In some embodiments, for example, the first main body portion 211 includes an insulating material, and the first barrier portion 212 includes a first metal material. The first main body portion 211 can include an inorganic insulating material, and in some embodiments, the first main body portion 211 can also include an organic insulating material. The first main body portion 211 including the organic insulating material can be disposed in the same layer with an organic film or layer in the display area AA, and the first main body portion 211 can be manufactured and formed simultaneously with the organic film or layer in the display area AA in the manufacturing process of the display panel 10.

With this arrangement, the first main body portion 211 of the first isolation body 210 serves as the electrically insulating portion for isolating the potential signals in the electrode layer of the display panel 10 from the external environment, thereby achieving a relatively good isolation effect, without affecting the function of the second isolation body 220.

On the basis of the above-described embodiment, the second main body portion 221 and the second barrier portion 222 in the second isolation body 220 can include either or both of the insulating material and the conductive material. For example, the second main body portion 221 includes a second metal material, and the second barrier portion 222 includes a third metal material. Optionally, the activity of the second metal material is greater than the activity of the first metal material, and/or, the activity of the second metal material is greater than the activity of the third metal material. Optionally, the material of the first barrier portion 212 can include titanium, the material of the second main body portion 221 can include aluminum, and the material of the second barrier portion 222 can include titanium.

The first barrier portion 212, the second main body portion 221, and the second barrier portion 222 each include a metal material, for example, selected from the group consisting of silver (Ag), copper (Cu), aluminum (Al), titanium (Ti), molybdenum (Mo), combinations thereof, and alloy materials of the above metals, such as an aluminum neodymium alloy (AlNd) or a molybdenum niobium alloy (MoNb). The first barrier portion 212, the second main body portion 221, and the second barrier portion 222 can be a single-layer structure, or a multi-layer composite structure such as Ti/Al/Ti, etc.

As described in the above embodiments, the first barrier portion 212 protrudes from the first main body portion 211 to form the undercut structure in the first isolation body 210. In some embodiments, optionally, along the direction from the isolation area VA to the display area AA, the length size of a protruding portion of the first barrier portion 212 protruding from the first main body portion 211 is d1, where 0.2 μm≤d1≤0.4 μm. For example, the length size dl of the protruding portion of the first barrier portion 212 protruding from the first main body portion 211 can specifically be 0.20 μm, 0.22 μm, 0.31 μm, 0.38 μm, 0.40 μm, etc. The above-described values are merely exemplary, and dl is not limited to the above-described values in the actual embodiments.

In the embodiments of the present disclosure, by setting the length size of the protruding portion of the first barrier portion 212 protruding from the first main body portion 211 to satisfy 0.2 μm≤d1≤0.4 μm, the undercut structure formed by the first main body portion 211 and the first barrier portion 212 can be relatively stable, thereby exerting a good isolation effect, and facilitating the processing and manufacture of the first isolation body 210.

As described in the above embodiments, the second barrier portion 222 protrudes from the second main body portion 221 to form the undercut structure in the second isolation body 220. In some embodiments, optionally, along the direction from the isolation area VA to the display area AA, the length size of a protruding portion of the second barrier portion 222 protruding from the second main body portion 221 is d2, where 0.2 μm≤d2≤0.4 μm. For example, the length size d2 of the protruding portion of the second barrier portion 222 protruding from the second main body portion 221 can specifically be 0.20 μm, 0.22 μm, 0.31 μm, 0.38 μm, 0.40 μm, etc. The above-described values are merely exemplary, and d2 is not limited to the above-described values in the actual embodiments.

On the basis of the above embodiment, optionally, along the direction perpendicular to the base substrate 100, the height size of the first main body portion 211 is h1, where 1 μm≤h1≤1.5 μm. For example, the height size h1 of the first main body portion 211 can specifically be 1.00 μm, 1.12 μm, 1.23 μm, 1.38 μm, 1.49 μm, 1.50 μm, etc. The above-described values are merely exemplary, and h1 is not limited to the above-described values in the actual embodiments.

Further, along the direction perpendicular to the base substrate 100, the sum of the height sizes of the first isolation body 210 and the second isolation body 220 is h2, where 2.1 μm≤h2≤2.3 μm. For example, the sum h2 of the height sizes of the first isolation body 210 and the second isolation body 220 can specifically be 2.10 μm, 2.12 μm, 2.20 μm, 2.28 μm, 2.30 μm, etc. The above-described values are merely exemplary, and h2 is not limited to the above-described values in the actual embodiments.

The first isolation structure 200 can relatively completely isolate the light-emitting layer and the electrode layer in the display panel 10 from the external environment, and can also isolate the potential signals in the electrode layer of the display panel 10 from the external environment, so as to avoid structural damages caused by electrochemical corrosion. Therefore, in order to further improve the isolation effect on the light-emitting layer and the electrode layer in the display panel 10, in some embodiments, optionally, the at least one first isolation structure 200 includes a plurality of first isolation structures 200, and the first isolation structures 200 are spaced from each other along the direction from the display area AA to the isolation area VA. By providing a plurality of first isolation structures 200, the plurality of first isolation structures 200 work together to ensure the effect of isolating the light-emitting layer, the electrode layer, and the potential signals in the electrode layer of the display panel 10 from the external environment, thereby improving the operation reliability thereof.

As described in the above embodiment, the plurality of first isolation structures 200 are spaced from each other. In some embodiments, the distance between two adjacent first isolation structures 200 is L1, where 8 μm≤L1≤12 μm. For example, the distance L1 between two adjacent first isolation structures 200 can specifically be 8.0 μm, 8.2 μm, 9.30 μm, 10.0 μm, 11.5 μm, 12.0 μm, etc. The above-described values are merely exemplary, and L1 is not limited to the above-described values in the actual embodiments.

The first isolation structures 200 are disposed in the isolation area VA, and the first isolation structures 200 and the display area AA are also spaced apart from each other. Optionally, the distance between one of the first isolation structures 200 and the display area AA is L2, where 8 μm≤L2≤12 μm. For example, the distance L2 between the first isolation structures 200 and the display area AA can specifically be 8.0 μm, 8.2 μm, 9.30 μm, 10.0 μm, 11.5 μm, 12.0 μm, etc. The above-described values are merely exemplary, and L2 is not limited to the above-described values in the actual embodiments. It can be understood that the distance L2 between the first isolation structures 200 and the display area AA means that the distance between one first isolation structure 200 most adjacent to the display area AA and the display area AA is L2.

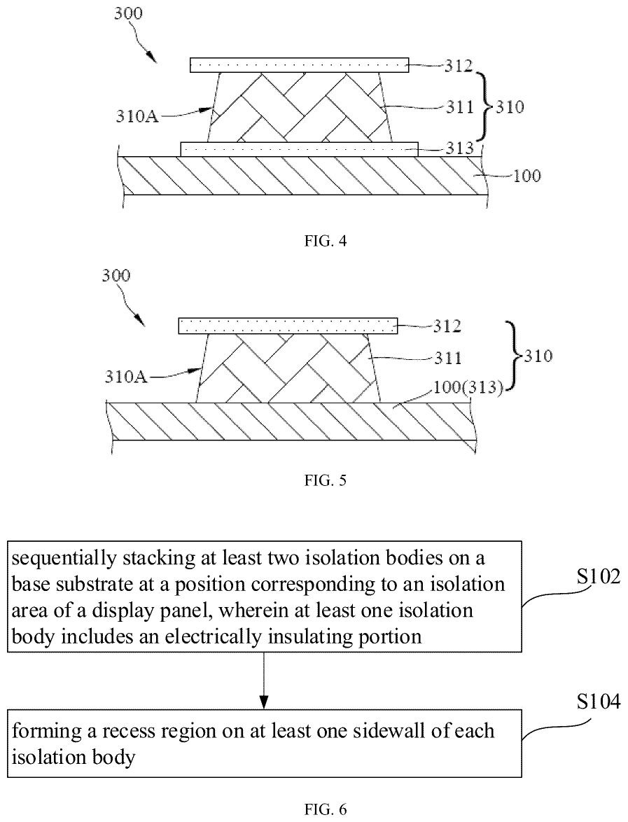

FIG. 4 shows a schematic structural cross-sectional view of a second isolation structure 300 of the display panel 10 according to an embodiment of the present disclosure.

On the basis of including one or more first isolation structures 200 in the isolation area VA of the display panel 10, referring to FIG. 4 in conjunction with FIG. 1, in some embodiments, optionally, the display panel 10 further includes at least one second isolation structure 300 located in the isolation area VA. The second isolation structure 300 and the first isolation structure 200 are spaced apart from each other. The second isolation structure 300 includes at least one isolation body stacked in sequence along the direction away from the base substrate 100, and at least one sidewall of the isolation body includes a recess region.

The specific structure of the second isolation structure 300 is similar to that of the first isolation structure 200, and the second isolation structure 300 can also be configured to partition the films or layers that could form the moisture transmission channels. Thus, the second isolation structure 300 can be disposed around the penetration area HA. As such, the moisture entering the display panel 10 from the penetration area HA can be prevented from reaching the display area AA along the moisture transmission channels.

The specific position of the second isolation structure 300 in the isolation area VA and the specific structure form of the second isolation structure 300 are not limited, as long as the second isolation structure 300 can partition the films or layers forming the moisture transmission channels. The second isolation structure 300 can cooperate with the first isolation structure 200 to ensure the effect of isolating the light-emitting layer, the electrode layer, and the potential signals in the electrode layer of the display panel 10 from the external environment, thereby improving the operation reliability. Moreover, compared with the first isolation structure 200, the overall structure of the second isolation structure 300 can be relatively simple, facilitating the processing and fabrication thereof.

The second isolation structure 300 includes at least one isolation body stacked in sequence along the direction away from the base substrate 100. In order to simplify the specific structure of the second isolation structure 300, in some embodiments, optionally, the second isolation structure 300 includes a third isolation body 310 stacked on the base substrate 100 The third isolation body 310 includes at least a third recess region 310A located on a sidewall of the third isolation body 310 adjacent to the display area AA. The third recess region 310A of the third isolation body 310, which is adjacent to the display area AA, can form a third undercut structure, so that the third isolation body 310 in the second isolation structure 300 can exert an isolation effect.

Regarding the specific structure of the third isolation body 310, for example, the third isolation body 310 includes a third main body portion 311 and a third barrier portion 312 located on the side of the third main body portion 311 away from the base substrate 100. The third recess region 310A is located on a sidewall the third main body portion 311 adjacent to the display area AA. The third barrier portion 312 protrudes from the third main body portion 311 along the direction from the isolation area VA to the display area AA.

In some embodiments, the recess region can be disposed around the sidewall of the isolation body, and each sidewall of the isolation body is provided with a recess region. Accordingly, the third recess region 310A can be disposed around the sidewall of the third main body portion 311, and each sidewall of the third main body portion 311 is provided with a third recess region 310A.

Optionally, an orthographic projection of the third barrier portion 312 on the base substrate 100 completely covers an orthographic projection of the third main body portion 311 on the base substrate 100; that is, along the direction perpendicular to the surface of the base substrate 100, the area of the projection pattern of the third barrier portion 312 on the surface of the base substrate 100 is larger than the area of the projection pattern of the third main body portion 311 on the surface of the base substrate 100, so that the projection pattern of the third barrier portion 312 on the surface of the base substrate 100 can completely cover the projection pattern of the third main body portion 311 on the surface of the base substrate 100, thereby forming the undercut structure in the third isolation body 310.

In some embodiments, optionally, the third isolation body 310 further includes a third base portion 313 located on a side of the third main body portion 311 adjacent to the base substrate 100; that is, the third base portion 313, the third main body portion 311, and the third barrier portion 312 are sequentially stacked on the base substrate 100, constituting the third isolation body 310.

The third base portion 313 is configured to carry the third main body portion 311. In order to improve the structural stability of the third isolation body 310, in some embodiments, optionally, an orthographic projection of the third base portion 313 on the base substrate 100 completely covers the orthographic projection of the third main body portion 311 on the base substrate 100; that is, along the direction perpendicular to the surface of the base substrate 100, the area of the projection pattern of the third base portion 313 on the surface of the base substrate 100 is larger than the area of the projection pattern of the third main body portion 311 on the surface of the base substrate 100, so that the projection pattern of the third base portion 313 on the surface of the base substrate 100 can completely cover the projection pattern of the third main body portion 311 on the surface of the base substrate 100.

In an embodiment, a sectional shape of the first main body portion 211 along the direction perpendicular to the base substrate 100 includes a rectangle, a trapezoid, or other irregular patterns; and/or a sectional shape of the second main body portion 221 along the direction perpendicular to the base substrate 100 includes a rectangle, a trapezoid, or other irregular patterns; and/or a sectional shape of the third main body portion 311 along the direction perpendicular to the base substrate 100 includes a rectangle, a trapezoid, or other irregular patterns.

FIG. 5 shows a schematic structural cross-sectional view of the second isolation structure 300 of the display panel 10 according to another embodiment of the present disclosure.

In some embodiments, the third base portion 313, the third main body portion 311, and the third barrier portion 312 are sequentially stacked on the base substrate 100 to form the third isolation body 310. Referring to FIG. 5 in conjunction with FIG. 1, similar to the first isolation body 210, in some other embodiments, at least a part of the base substrate 100 functions as the third base portion 313; that is, the third base portion 313 and the base substrate 100 can be integrated as one piece without an additional third base portion 313, thereby simplifying the fabrication process thereof. In this case, the third isolation body 310 includes a portion of the base substrate 100, the third main body portion 311, and the third barrier portion 312 that are sequentially stacked.

The first isolation structure 200 and the second isolation structure 300 are both disposed in the isolation area VA, and their relative positions are not limited. In some embodiments, optionally, the second isolation structure 300 is located on the side of the first isolation structure 200 away from the display area AA of the display panel 10. Thus, the distance between the second isolation structure 300 and the display area AA is greater than the distance between the first isolation structure 200 and the display area AA, so that the first isolation structure 200 can provide a relatively tight isolation effect at a position relatively close to the display area AA, thereby exerting a relatively good protecting effect for the display area AA.

In order to further improve the isolation effect of the second isolation structure 300, in some embodiments, optionally, the at least one second isolation structure 300 includes a plurality of second isolation structures 300, and the second isolation structures 300 are spaced from each other along the direction from the display area AA to the isolation area VA. By providing a plurality of second isolation structures 300, the plurality of second isolation structures 300 work together to ensure the stability of the isolation effect of the second isolation structure and improve the operation reliability of the second isolation structure.

When the isolation area VA of the display panel 10 includes one or more first isolation structures 200 and a plurality of second isolation structures 300, the arrangement and the positional relationship of the first isolation structure(s) 200 and the second isolation structures 300 are not limited. For example, the first isolation structure(s) 200 and the second isolation structures 300 can be alternately arranged. In some embodiments, at least one first isolation structure 200 can be located at a side of the plurality of second isolation structures 300 away from the display area AA, which can ensure a relatively good isolation effect, improving the reliability. In some embodiments, at least one first isolation structure 200 can be disposed at each side of the plurality of second isolation structures 300, which can ensure a relatively good isolation effect, improving the reliability. In some other embodiments, optionally, all of the second isolation structures 300 are located on the side of the first isolation structure(s) 200 away from the display area AA of the display panel 10. That is, the one or more first isolation structures 200 are disposed at a position adjacent to the display area AA, and the second isolation structures 300 are disposed at a position away from the display area AA. As such, the first isolation structure(s) 200 can provide a relatively tight isolation effect at the position relatively close to the display area AA, thereby exerting a relatively good protecting effect for the display area AA.

The second isolation structures 300 are spaced apart from each other. For example, the distance between two adjacent second isolation structures 300 is L3, where 8 μm≤L3≤12 μm. For example, the distance L3 between two adjacent second isolation structures 300 can specifically be 8.0 μm, 8.2 μm, 9.30 μm, 10.0 μm, 11.5 μm, 12.0 μm, etc. The above-described values are merely exemplary, and L3 is not limited to the above-described values in the actual embodiments.

The second isolation structure 300 and the first isolation structure 200 are also spaced apart from each other. For example, the distance between the second isolation structure 300 and the first isolation structure 200 is L4, where 8 μm≤L4≤12 μm. For example, the distance L4 between the second isolation structure 300 and the first isolation structure 200 can specifically be 8.0 μm, 8.2 μm, 9.30 μm, 10.0 μm, 11.5 μm, 12.0 μm, etc. The above-described values are merely exemplary, and L4 is not limited to the above-described values in the actual embodiments. It can be understood that the distance L4 between the second isolation structure 300 and the first isolation structure 200 refers to a distance between a second isolation structure 300 and a first isolation structure 200 that are adjacent to each other.

Referring still to FIG. 1, in an embodiment, the total number of the plurality of first isolation structures 200 and the plurality of second isolation structures 300 is in a range from 4 to 8. Optionally, the total number of the plurality of first isolation structures 200 and the plurality of second isolation structures 300 is in a range from 5 to 7, specifically can be 5, 6 or 7. With this arrangement, the stability of the isolation structures can be further improved on the basis of narrowing the range occupied by the isolation area VA.

In the display panel 10, the isolation area VA is located on at least one side of the display area AA. In some embodiments, an orthographic projection of the display area AA on the base substrate 100 includes a first projection pattern, and an orthographic projection of the isolation area VA on the base substrate 100 includes a second projection pattern. The first projection pattern surrounds at least a part of the second projection pattern; that is, the display area AA encloses at least a part of the isolation area VA. In this case, the space in the isolation area VA can be isolated from the display area AA.

On the basis of the above embodiment, optionally, the display panel 10 further includes a penetration area HA, an orthographic projection of the penetration area HA on the base substrate 100 includes a third projection pattern. The second projection pattern surrounds at least a part of the third projection pattern; that is, the isolation area VA encloses at least a part of the penetration area HA. In this case, the display area AA and the penetration area HA located on opposite sides of the isolation area VA can be isolated from each other by the isolation area VA.

The shape of the isolation area VA varies with the shape of the penetration area HA. For example, in the display panel 10 of the “notch screen”, the penetration area HA is substantially trapezoidal, with one of the two parallel sides being flush with the display area AA. In this case, the isolation area VA surrounds the other of the two parallel sides and two lateral sides of the penetration area HA, by which the isolation area VA can isolate the display area AA from the trapezoidal penetration area HA. In some other embodiments, in the display panel 10 of the “hole-punch screen”, the penetration area HA can be circular or quasi-circular, and optionally, the second projection pattern includes an annular shape, and the second projection pattern completely surrounds the third projection pattern. In this case, the annular isolation area VA surrounds the periphery of the penetration area HA and completely encircles the penetration area HA.

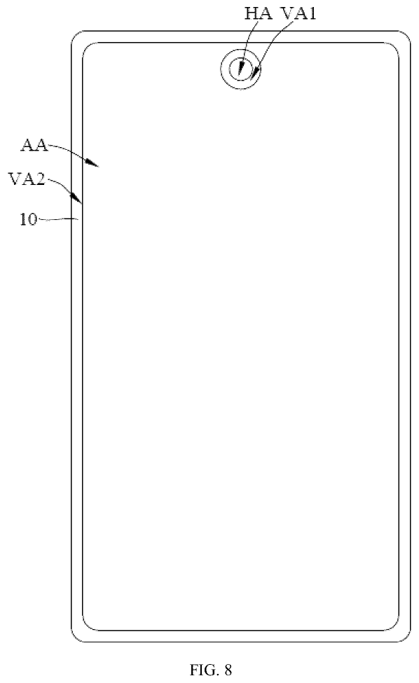

In some other embodiments, the isolation area VA can be further disposed at an outer side of the display area AA to isolate the display area AA from the external environment. Optionally, the orthographic projection of the isolation area VA on the base substrate 100 further includes a fourth projection pattern, and the fourth projection pattern surrounds at least a part of the first projection pattern; that is, the isolation area VA encloses at least a part of the display area AA. In this case, the isolation area VA can isolate the display area AA located therein from the external environment. Specifically, referring to FIG. 8, the orthographic projection of the second isolation area VA2 on the base substrate 100 is the fourth projection pattern, and the orthographic projection of the first isolation area VA1 on the base substrate 100 is the second projection pattern.

The shape of the isolation area VA varies with the shape of the display area AA. For example, the display area AA can be quadrilateral or quasi-quadrilateral. Optionally, the fourth projection pattern includes an annular shape, and the fourth projection pattern completely surrounds the first projection pattern. In this case, the annular isolation area VA surrounds the periphery of the display area AA and completely encircles the display area AA.

In some embodiments, optionally, the display panel 10 further includes at least one dam structure 400 located in the isolation area VA. The at least one first isolation structure 200 includes a plurality of first isolation structures 200. At least one first isolation structure 200 is located on the side of the dam structure 400 adjacent to the display area AA, and/or at least one first isolation structure 200 is located on the side of the dam structure 400 away from the display area AA (specifically referring to FIG. 1). The dam structure 400 is configured to isolate a portion of an encapsulation layer 700 within the display area AA, preventing the portion of the encapsulation layer 700 from entering the isolation area VA. Accordingly, the specific structure of the dam structure 400 is not limited herein. The dam structure 400 can also include a multi-layer stacked structure for isolation. For example, the dam structure 400 can include a first layer structure disposed in the same layer with the first planarization layer 510, a second layer structure disposed in the same layer with the second planarization layer 520, and a third layer structure disposed in the same layer with the pixel definition layer 530.

In another embodiment, the number of the dam structure 400 is plural, and the relative positional relationship between the plurality of first isolation structures 200 and the plurality of dam structures 400 can be in various ways. For example, at least one first isolation structure 200 can be located between the dam structures 400, etc., which is not limited herein.

The encapsulation layer 700 can block external impurities, moisture, etc., preventing them from entering the display panel 10 to corrode the internal structures of the display panel 10, thereby protecting other structures in the display panel 10. In the embodiment as shown in FIG. 1, the encapsulation layer 700 includes a first sub-encapsulation layer 710, a second sub-encapsulation layer 720, and a third sub-encapsulation layer 730 that are stacked in sequence, wherein the first sub-encapsulation layer 710 can be filled between two adjacent light-emitting function portions 600, and the second sub-encapsulation layer 720 covers the surfaces of the light-emitting function portions 600 and the first sub-encapsulation layer 710 away from the base substrate 100.

The encapsulation layer 700 can be a single-layer structure made of an inorganic material or an organic material, or can be a stacked-layer structure made of at least one of the inorganic material or the organic material. The materials of the first sub-encapsulation layer 710 and the second sub-encapsulation layer 720 can be the same or different. In some embodiments, the first sub-encapsulation layer 710 is an inorganic material layer, and the second sub-encapsulation layer 720 is an organic material layer.

In order to improve the overall encapsulation effect of the encapsulation layer 700, the encapsulation layer 700 can further include a third sub-encapsulation layer 730. The third sub-encapsulation layer 730 covers the surface of the second sub-encapsulation layer 720 away from the first sub-encapsulation layer 710, and the third sub-encapsulation layer 730 can be an inorganic material layer.

FIG. 6 shows a flowchart of a method for manufacturing a display panel 10 according to an embodiment of the present disclosure.

Referring to FIG. 6 in conjunction with FIGS. 1 to 5, an embodiment of the present disclosure further provides a method for manufacturing a display panel 10, and the manufacturing method includes the following steps:

S102: sequentially stacking at least two isolation bodies on a base substrate 100 at a position corresponding to an isolation area VA of a display panel 10, wherein at least one isolation body includes an electrically insulating portion; and

S104: forming a recess region on at least one sidewall of each isolation body.

In step S102, since the display area AA of the display panel 10 includes a plurality of insulating layers and a source/drain metal layer are stacked with the insulating layers, the isolation body in the isolation area VA can be fabricated synchronously with the insulating layers and the source/drain metal layer in the display area AA. Specifically, the insulating layer can be formed on the base substrate 100, the portion of the insulating layer in the isolation area VA forming the first isolation body 210 including the electrically insulating portion. Then the source/drain metal layer is stacked on the insulating layer, the portion of the source/drain metal layer in the isolation area VA forming the second isolation body 220 stacked on the first isolation body 210.

Subsequently, the recess region is formed on at least one sidewall of the isolation body by step S104. For example, in step S104, the first recess region 210A can be formed on the sidewall of the first isolation body 210 by using a dry asher process, and the second recess region 220A can be formed on the sidewall of the second isolation body 220 by using a wet etching process. The entire manufacturing method has few steps and a simple process. The method for manufacturing the display panel 10 according to the embodiment of

the present disclosure has a simple and convenient process. The first isolation structure 200 is disposed in the isolation area VA of the display panel 10, the first isolation structure 200 includes at least two isolation bodies sequentially stacked along the direction away from the base substrate 100, and at least one sidewall of each isolation body includes a recess region. As a result, the height of the first isolation structure 200 in the direction perpendicular to the base substrate 100 is relatively great, and the light-emitting layer and the electrode layer in the display panel 10 can be relatively completely isolated from the external environment. Moreover, as at least one isolation body includes an electrically insulating portion, the potential signals in the electrode layer of the display panel 10 can be isolated from the external environment, avoiding structural damages caused by electrochemical corrosion, thereby improving the operation reliability of the first isolation structure 200.

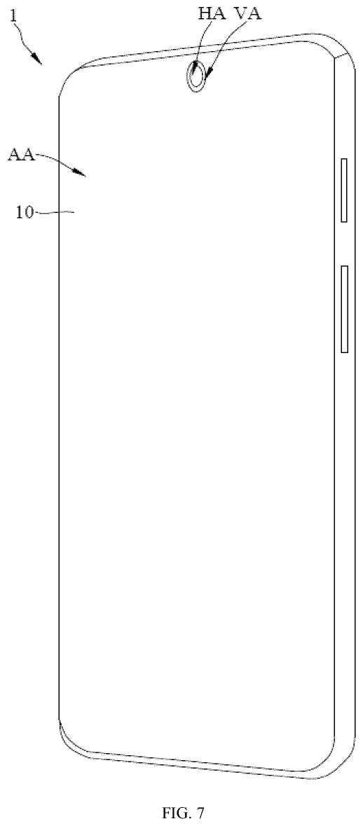

FIG. 7 shows an overall schematic structural view of a display device 1 according to an embodiment of the present disclosure.

Referring to FIG. 7 in conjunction with FIG. 1, an embodiment of the present disclosure further provides a display device 1, and the display device 1 includes the display panel 10 as described in any one of the above embodiments.

The display panel 10 disclosed in the embodiments of the present disclosure is applied to the display device 1 to provide a display function, and the display device 1 can be any product or component having a display function, including but not limited to a mobile phone, a tablet computer, a notebook computer, an electronic reader, a wearable device, a remote controller, a television, a desktop computer, an in-vehicle device, or the like.

The display panel 10 includes the penetration area HA, the isolation area VA, and the display area AA. The penetration area HA can be circular. The isolation area VA is located outside the penetration area HA and disposed around the penetration area HA. The isolation area VA can be annular. The display area AA is located outside the isolation area VA and disposed around the isolation area VA. By adopting the above-described display panel 10, in the display device 1 according to the embodiment of the present disclosure, the light-emitting layer and the electrode layer in the display panel 10 can be relatively completely isolated from the external environment, and the potential signals in the electrode layer of the display panel 10 can be isolated from the external environment, avoiding structural damages caused by electrochemical corrosion, thereby improving the operation reliability of the first isolation structure 200.

FIG. 8 shows a schematic structural view of a display panel 10 in a display device 1 according to another embodiment of the present disclosure.

As shown in FIG. 8, in some other embodiments, the display panel 10 includes the penetration area HA and the display area AA. The isolation area VA includes the first isolation area VA1 and the second isolation area VA2. The penetration area HA can be circular. The first isolation area VA1 is located outside the penetration area HA and disposed around the penetration area HA. The first isolation area VA1 can be annular. The display area AA is located outside the first isolation area VA1 and disposed around the first isolation area VA1. The second isolation area VA2 is located outside the display area AA and disposed around the display area AA. The second isolation area VA2 can be polygonal.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described examples are only several embodiments of the present disclosure, and the descriptions are relatively specific and detailed, but they should not be construed as limiting the scope of the present disclosure. It should be understood that various modifications and improvements can be made by those of ordinary skill in the art without departing from the concept of the present disclosure, and all fall within the protection scope of the present disclosure. Therefore, the patent protection scope of the present disclosure shall be defined by the appended claims.

What is claimed is:

1. A display panel, comprising a display area and an isolation area located on at least one side of the display area, the display panel comprising:
a base substrate, and
at least one first isolation structure located in the isolation area, the at least one first isolation structure comprising at least two isolation bodies sequentially stacked along a direction away from the base substrate, at least one sidewall of each of the at least two isolation bodies comprising a recess region;
wherein at least one isolation body comprises an electrically insulating portion.

2. The display panel according to claim 1, wherein the at least one first isolation structure comprises a first isolation body and a second isolation body sequentially stacked in the direction away from the base substrate, the first isolation body at least comprises a first recess region located on a sidewall of the first isolation body adjacent to the display area, the second isolation body at least comprises a second recess region located on a sidewall of the second isolation body adjacent to the display area, and the first isolation body comprises the electrically insulating portion.

3. The display panel according to claim 2, wherein
the first isolation body comprises a first main body portion and a first barrier portion located on a side of the first main body portion away from the base substrate, the first recess region is located on a sidewall of the first main body portion, and the first barrier portion protrudes from the first main body portion along a direction from the isolation area to the display area;
the second isolation body comprises a second main body portion and a second barrier portion located on a side of the second main body portion away from the base substrate, the second recess region is located on a sidewall of the second main body portion, and the second barrier portion protrudes from the second main body portion along the direction from the isolation area to the display region.

4. The display panel according to claim 3, wherein
an orthographic projection of the first barrier portion on the base substrate completely covers an orthographic projection of the first main body portion on the base substrate;
an orthographic projection of the second barrier portion on the base substrate completely covers an orthographic projection of the second main body portion on the base substrate.

5. The display panel according to claim 4, wherein
the orthographic projection of the first barrier portion on the base substrate completely covers the orthographic projection of the second main body portion on the base substrate.

6. The display panel according to claim 3, wherein
the recess region is disposed around the sidewall of the isolation body, the first recess region is disposed around the sidewall of the first main body portion, and the second recess region is disposed around the sidewall of the second main body portion.

7. The display panel according to claim 3, wherein the first isolation body further comprises a first base portion located on a side of the first main body portion adjacent to the base substrate;
the first base portion satisfies:
an orthographic projection of the first base portion on the base substrate completely covers the orthographic projection of the first main body portion on the base substrate; or
at least a portion of the base substrate functions as the first base portion.

8. The display panel according to claim 3, wherein the second isolation body further comprises a second base portion located on a side of the second main body portion adjacent to the base substrate;
the second base portion satisfies:
an orthographic projection of the second base portion on the base substrate completely covers the orthographic projection of the second main body portion on the base substrate; or
the first barrier portion and the second base portion are integrated as one piece.

9. The display panel according to claim 3, wherein the first main body portion comprises an insulating material, and the first barrier portion comprises a first metal material,
the second main body portion comprises a second metal material, the second barrier portion comprises a third metal material;
an activity of the second metal material is greater than an activity of the first metal material; and
an activity of the second metal material is greater than an activity of the third metal material.

10. The display panel according to claim 3, wherein along the direction from the isolation area to the display area, a length size of a protruding portion of the first barrier portion protruding from the first main body portion is d1, where 0.2 μm≤d1≤0.4 μm;
along the direction from the isolation area to the display area, a length size of a protruding portion of the second barrier portion protruding from the second main body portion is d2, where 0.2 μm≤d2≤0.4 μm;
along a direction perpendicular to the base substrate, a height size of the first main body portion is h1, where 1 μm≤h1≤1.5 μm; and
along the direction perpendicular to the base substrate, a sum of the height sizes of the first isolation body and the second isolation body is h2, where 2.1 μm≤h2≤2.3 μm.

11. The display panel according to claim 1, wherein the at least one first isolation structure comprises a plurality of first isolation structures, the plurality of first isolation structures are spaced from each other along the direction from the display area to the isolation area;
a distance between two adjacent first isolation structures of the plurality of first isolation structures is L1, where 8 μm≤L1≤12 μm; and
a distance between one of the plurality of first isolation structures and the display area is L2, where 8 μm≤L2≤12 μm.

12. The display panel according to claim 1, further comprising at least one second isolation structure located in the isolation area, the at least one second isolation structure and the at least one first isolation structure are spaced from each other, the at least one second isolation structure includes at least one isolation body sequentially stacked along the direction away from the base substrate, at least one sidewall of the isolation body comprises a recess region;
the at least one second isolation structure comprises a third isolation body stacked on the base substrate, and the third isolation body includes a third recess region located at least on a sidewall of the third isolation body adjacent to the display area;
the third isolation body comprises a third main body portion and a third barrier portion located on a side of the third main body portion away from the base substrate, the third recess region is located on a sidewall of the third main body portion, and the third barrier portion protrudes from the third main body portion along the direction from the isolation area to the display area.

13. The display panel according to claim 12, wherein the recess region is disposed around the sidewall of the isolation body, the third recess region is disposed around the sidewall of the third main body portion;
an orthographic projection of the third barrier portion on the base substrate completely covers an orthographic projection of the third main body portion on the base substrate;
the third isolation body further comprises a third base portion located on a side of the third main body portion adjacent to the base substrate; and
an orthographic projection of the third base portion on the base substrate completely covers the orthographic projection of the third main body portion on the base substrate.

14. The display panel according to claim 12, wherein the at least one second isolation structure is located on a side of the at least one first isolation structure away from the display area;
the at least one the second isolation structure comprises a plurality of second isolation structures, the plurality of second isolation structures are spaced from each other along the direction from the display area to the isolation area; and
all of the plurality of second isolation structures are located on the side of the at least one first isolation structure away from the display area.

15. The display panel according to claim 14, wherein
a distance between two adjacent second isolation structures of the plurality of second isolation structures is L3, where 8 μm≤L3≤12 μm; and
a distance between one of the plurality of second isolation structures and the at least one first isolation structure is L4, where 8 μm≤L4≤12 μm.

16. The display panel according to claim 1, wherein
an orthographic projection of the display area on the base substrate comprises a first projection pattern, an orthographic projection of the isolation area on the base substrate comprises a second projection pattern, and the first projection pattern surrounds at least a part of the second projection pattern.

17. The display panel according to claim 16, wherein
the display panel further comprises a penetration area, an orthographic projection of the penetration area on the base substrate comprises a third projection pattern, and the second projection pattern surrounds at least a part of the third projection pattern;
the second projection pattern comprises an annular shape, and the second projection pattern completely surrounds the third projection pattern; or
the orthographic projection of the isolation area on the base substrate further comprises a fourth projection pattern, and the fourth projection pattern surrounds at least a part of the first projection pattern;
the fourth projection pattern comprises an annular shape, and the fourth projection pattern completely surrounds the first projection pattern.

18. The display panel according to claim 1, wherein
the display panel further comprises at least one dam structure located in the isolation area, the at least one first isolation structure comprises a plurality of first isolation structures; at least one of the plurality of first isolation structures is located on a side of the dam structure adjacent to the display area, and at least one of the plurality of first isolation structures is located on a side of the dam structure away from the display area.

19. A method for manufacturing the display panel according to claim 1, comprising:
sequentially stacking at least two isolation bodies on a base substrate at a position corresponding to an isolation area of a display panel, at least one isolation body comprising an electrically insulating portion; and
forming a recess region on at least one sidewall of each isolation body.

20. A display device, comprising the display panel according to claim 1.
